(19) United States
(12) Patent Application Publication
(10) Pub. No.: US 2025/0300066 A1
(43) Pub. Date: Sep. 25, 2025

(54) FORMING METAL LINE AND VIA STRUCTURE

(71) Applicant: INTERNATIONAL BUSINESS MACHINES CORPORATION, ARMONK, NY (US)

(72) Inventors: Oscar van der Straten, Guilderland Center, NY (US); Koichi Motoyama, Clifton Park, NY (US); Chih-Chao Yang, Glenmont, NY (US)

(21) Appl. No.: 18/610,646

(22) Filed: Mar. 20, 2024

(51) Int. Cl. H01L 23/522; H01L 21/768; H01L 23/528; H01L 23/532

(52) U.S. Cl. CPC H01L 23/5226; H01L 21/76816; H01L 21/76847; H01L 21/76877; H01L 23/528; H01L 23/53266

(57) ABSTRACT

A metal structure which spans vertically across a M1 metal line level and a V1 via level above the M1 metal line level, where the metal structure includes both a metal line in the M1 metal line level and a via in the V1 via level, where an individual metal grain of the conductive metal structure spans from the metal line in the M1 metal line level and the via in the V1 via level. A metal line in a M1 metal line level and a set of vias in a V1 via level above the M1 metal line level, where the metal line and the set of vias are one continuous metal structure.

### BACKGROUND

The present invention generally relates to semiconductor structures, and more particularly to forming metal line and via structure with low resistance.

Back end of line (BEOL) is the portion of integrated circuit where the individual devices (transistors, capacitors, resisters, etc.) get interconnected with one or more metallization layers. The BEOL begins above the front-end-of-line region which contains the devices themselves. In general, the BEOL includes contacts, insulating layers (dielectrics), metal levels, and bonding sites for chip-to-package connections and wiring for metal lines. For multi-level interconnection of advanced semiconductor devices, metal via structures are used to enable metal-to-metal contact to the levels below. Via structures typically include both a main conductor material and several suitable nucleation, liner and/or barrier layers. These layers ensure adequate adhesion to the surrounding dielectric as well as good nucleation and growth of the main conductor material. The liner and barrier materials typically exhibit high resistivity, and the presence of such high-resistivity liner and barrier layers in a via structure results in high via resistance which negatively impacts device performance. In addition, the various interfaces formed by these liner and barrier layers can add resistance components to the overall via resistance. There is a need for via structures with reduced via resistance.

### SUMMARY

According to an embodiment of the present invention, a semiconductor structure is provided. The semiconductor structure including a metal structure which spans vertically across a M1 metal line level and a V1 via level above the M1 metal line level, where the metal structure includes both a metal line in the M1 metal line level and a via in the V1 via level, where an individual metal grain of the metal structure spans across the metal line in the M1 metal line level and the via in the V1 via level.

According to an embodiment of the present invention, a semiconductor structure is provided. The semiconductor structure including a metal line in a M1 metal line level and a via in a V1 via level above the M1 metal line level, where the metal line and the via form one continuous metal structure.

According to an embodiment of the present invention, a semiconductor structure is provided. The semiconductor structure including a metal line in a M1 metal line level and a set of vias in a V1 via level above the M1 metal line level, where the metal line and the set of vias are one continuous metal structure.

### BRIEF DESCRIPTION OF THE DRAWINGS

The following detailed description, given by way of example and not intended to limit the invention solely thereto, will best be appreciated in conjunction with the accompanying drawings, in which:

FIGS. 1 and 2 are each a cross-sectional view of a structure along section lines X-X and Y-Y, respectively, shown during an intermediate step of fabrication, according to an embodiment of the invention;

FIG. 3 is a cross-sectional view of the structure along section line X-X and illustrates formation of a metal wire opening, according to an embodiment of the invention;

FIG. 4 is a cross-sectional view of the structure along section line X-X and illustrates deposition of a barrier layer, according to an embodiment of the invention;

FIG. 5 is a cross-sectional view of the structure along section line X-X and illustrates deposition of a conductive material layer, according to an embodiment of the invention;

FIG. 6 is a cross-sectional view of the structure along section line X-X and illustrates patterning of the conductive material layer, according to an embodiment of the invention;

FIG. 7 is a cross-sectional view of the structure along section line X-X and illustrates formation of a dielectric cap layer, according to an embodiment of the invention;

FIGS. 8, 9 and 10 are each a cross-sectional view of the structure along section lines X-X, X-X and Y-Y, respectively, and illustrate removal of a portion of the dielectric cap layer, formation of an inter-layer dielectric and formation of an upper metal level, according to an embodiment of the invention; and

FIG. 11 is a cross-sectional view of an alternate structure along section line X-X, according to another embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As stated above, back end of line (BEOL) is the portion of an integrated circuit where the individual devices (transistors, capacitors, resisters, etc.) get interconnected with one or more metallization layers. The BEOL generally begins above the front-end-of-line region which contains the devices themselves. In general, the BEOL includes contacts, insulating layers (dielectrics), metal levels, bonding sites for chip-to-package connections and wiring for metal lines. For multi-level interconnection of advanced semiconductor devices, metal via structures are used to enable metal-to-metal contact to the levels below. Via structures typically include both a main conductor material and several suitable nucleation, liner and/or barrier layers. These layers ensure adequate adhesion to the surrounding dielectric as well as good nucleation and growth of the main conductor material. The liner and barrier materials typically exhibit high resistivity, and the presence of such high-resistivity liner and barrier layers in a via structure results in high via resistance which negatively impacts device performance. In addition, the various interfaces formed by these liner and barrier layers can add resistance components to the overall via resistance. There is a need for via structures with reduced via resistance.

The present invention generally relates to semiconductor structures, and more particularly to a simultaneously formed metal line and via structure with low resistance. The via structure with low resistance is formed with a novel simultaneous metallization of a metal line and a group of one or more vias extending above the metal line. A trench for a metal line is formed on a barrier layer which separates the to be formed metal line from a surrounding inter-layer dielectric. The trench is formed in a metal line level of the semiconductor structure. A conductive material layer is formed, filling the trench to form the metal line, and extending above the metal line into a via level above the metal line level. Portions of the conductive material layer are removed in the via level, such that remaining portions of the conductive material layer function as vias. A dielectric cap is formed on an upper horizontal surface of the inter-layer dielectric surrounding the metal line and covering a portion of a vertical side surface of the vias. In an alternate embodiment, the dielectric cap covers an entire vertical side surface of the vias. A second inter-level dielectric surrounds the vias in the via level. An additional metal line level is formed above the via level.

The resulting structure has a conductive material layer spanning the metal line level and the via level, and the conductive material layer is both one or more metal lines in the metal line level and one or more vias in the via level. The resulting metal lines in the metal line level and the vias in the via level were formed during the same processing step. The metal lines in the metal line level are formed by damascene. The vias in the via level are formed by subtractive metal etch.

The resulting structure has a reduced via resistance between a metal line of the metal line level and a via of the via level, as the continuous formation of the conductive material layer forms both the metal line and the via and thus there is no liner nor barriers between the metal line and the via.

The simultaneous metallization of the metal line and the via extends scalability of via structures due to an enlarged process window for reducing a critical dimension of the via without an associated large increase in via resistance.

The simultaneous metallization of the metal line and the via enables the formation of large metal grains, where an individual metal grain may span an area covering both the metal line below and the metal via above.

The simultaneous metallization of the metal line and the via enables a novel solution for providing a low resistance via structure.

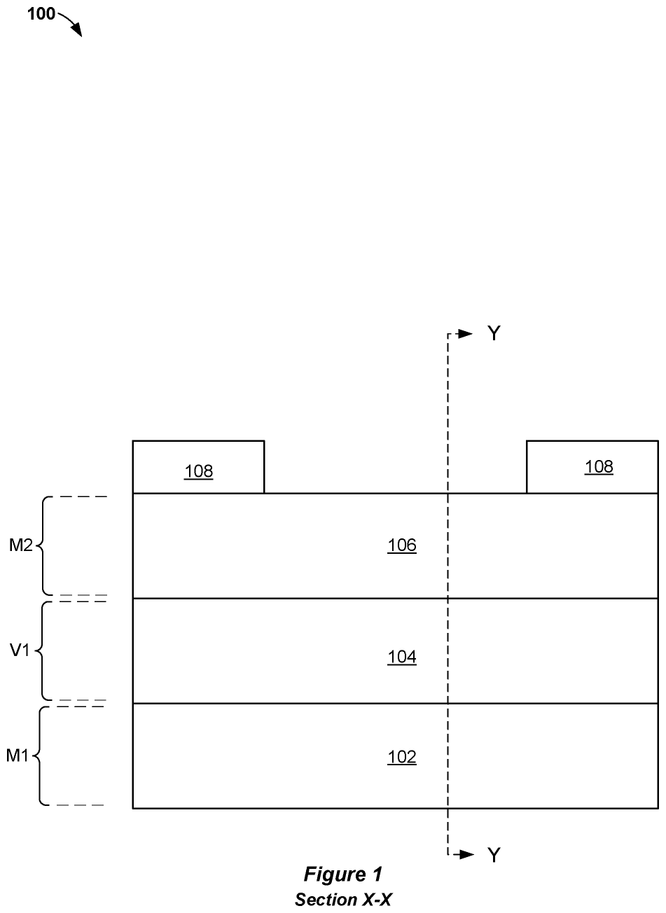

Exemplary embodiments of a via structure with low resistance are described in detail below by referring to the accompanying drawings in FIGS. 1 to 11. Those skilled in the art will readily appreciate that the detailed description given herein with respect to these figures is for explanatory purposes as the invention extends beyond these limited embodiments.

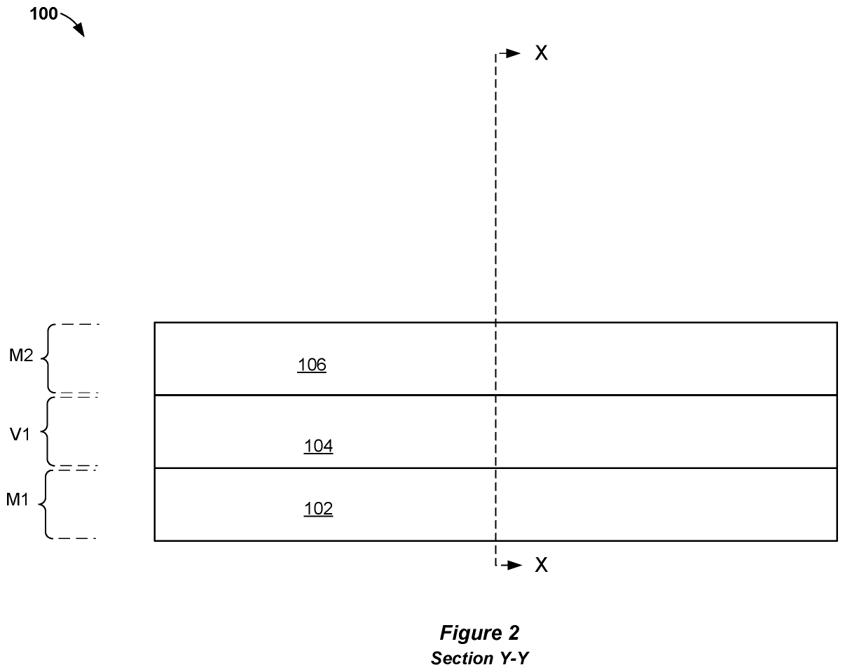

Referring now to FIGS. 1 and 2, a semiconductor structure 100 (hereinafter “structure”) is shown during an intermediate step of a method of fabricating a via, according to an embodiment of the invention. FIGS. 1 and 2 are each a cross-sectional view of the structure 100 along section lines X-X and Y-Y, respectively. The cross-section shown in FIG. 1 is taken in a direction that is perpendicular to the direction taken for the cross-section of FIG. 2. The structure 100 may be formed or provided. The structure 100 may include a M1 metal line level, a V1 via level and a M2 metal line level. The structure 100 may include an inter-layer dielectric (hereinafter “ILD”) 102 in the M1 metal line level, an ILD 104 in the V1 via level above the M1 metal line level, and an ILD 106 in the M2 metal line level above the V1 via level. There may be a hard mask 108 patterned on an upper surface of the structure, on the ILD 106.

The structure 100 may include several back end of line (“BEOL”) layers on a substrate. In general, the BEOL is the portion of integrated circuit where the individual devices (transistors, capacitors, resistors, etc.) are interconnected with wiring on the wafer. The substrate (not shown) may include a bulk semiconductor or a layered semiconductor such as Si/SiGe, a silicon-on-insulator (SOI), or a SiGe-on-insulator (SGOI). Bulk substrate materials may include undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. In other embodiments, the substrate (not shown) may represent a device region, such as the front-end-of-line, or a prior metallization level in the back-end-of-line, such as the M1 metal line level, the V1 via level and the M2 metal line level. In some cases, the substrate (not shown) may generally be referred to as a wafer.

The ILD 102 may be formed by depositing or growing a dielectric material on the BEOL layers, followed by a chemical mechanical polishing (CMP) or etch steps. The ILD 102 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the ILD 102 may include one or more layers. In an embodiment, the ILD 102 may include any dielectric material such as silicon oxide (SiOx), silicon nitride (SiNx), silicon boron carbonitride (SiBCN), SiCN, a low-k dielectric material (with k<4.0), including but not limited to, silicon oxide, spin-on-glass, a flowable oxide, a high-density plasma oxide, borophosphosilicate glass (BPSG), or any combination thereof or any other suitable dielectric material. The M1 metal line level includes metal wires (not shown) formed in trenches (not shown) in the ILD 102, which provide wiring circuitry and connections between vias in layers both above and below the M1 metal line level. The layer above the M1 metal line level is the V1 via level.

The ILD 104 may be formed of a material and as described for the ILD 102. The V1 via level includes vias (not shown) formed in openings (not shown) in the ILD 104, which provide connections between metal line levels in layers both above and below the V1 via level. The layer above the V1 via level is the M2 metal line level. The layer below the V1 via level is the M1 metal line level.

The ILD 106 may be formed of a material and as described for the ILD 102. The M2 metal line level includes metal wires (not shown) formed in trenches (not shown) in the ILD 106, which provide connections between metal line levels in layers both above and below the M2 metal line level. The layer below the M2 metal line level is the V1 via level.

The hard mask 108 is formed by methods known in the arts and patterned.

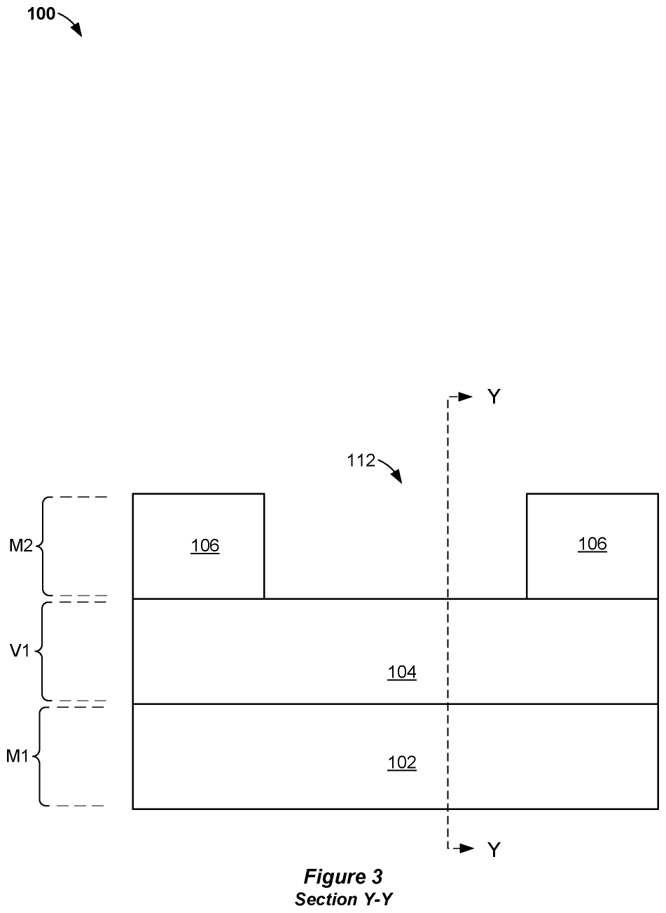

Referring now to FIG. 3, the structure 100 is shown according to an embodiment of the invention. FIG. 3 is a cross-sectional view of the structure 100 along section line X-X. Portions of the ILD 106 may be removed, forming a metal wire opening 112.

The metal wire opening 112 may be formed by methods known in the arts by selective removal of a portion of the ILD 106 which was not covered by the hard mask 108, exposing an upper horizontal surface of the ILD 104. The metal wire opening 112 may be a trench. There may be any number of metal wire openings 112 in the ILD 106.

In an embodiment, the ILD 104 may include a material with a different etch rate than the material of the ILD 106 to facilitate selective removal of the ILD 106.

The hard mask 108 may be removed by methods known in the arts.

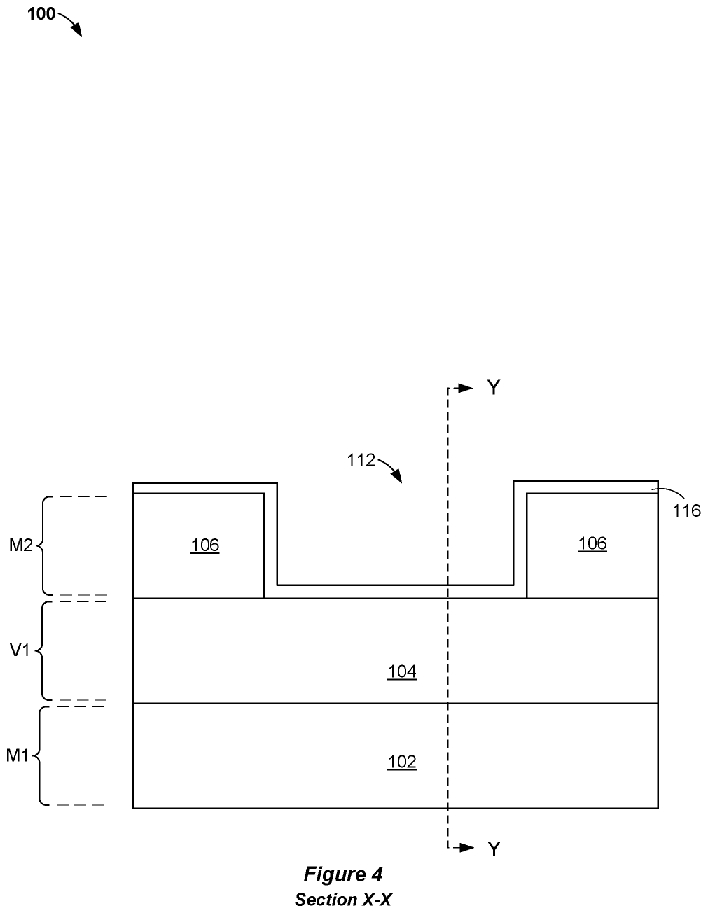

Referring now to FIG. 4, the structure 100 is shown according to an embodiment of the invention. FIG. 4 is a cross-sectional view of the structure 100 along section line X-X. A barrier layer 116 may be formed.

The barrier layer 116, or nucleation layer, is formed by conformally depositing a barrier material over the structure 100 according to known techniques. Specifically, the barrier material is conformally deposited on a top and on sidewall surfaces of the ILD 106, and on an exposed upper horizontal surface of the ILD 104, lining the metal wire opening 112. As used herein, “conformal” is meant that a material layer has a continuous thickness, or substantially continuous thickness. For example, a continuous or a same thickness generally means a first thickness as measured from a bottom surface to a topmost surface that is the same as a second thickness as measured from an inner sidewall surface to an outer sidewall surface.

As well known by a person skilled in the art, the barrier layer 116 is typically applied to create a diffusion barrier between the surrounding dielectrics (ILD 104, 106). As such, the barrier layer 116 would be designed to prevent diffusion of any subsequently deposited conductive material into the surrounding dielectrics (ILD 104, 106). According to embodiments of the present invention, the barrier layer 116 is composed of any known suitable barrier materials, for example, metal nitrides. In an embodiment, the barrier layer 116 includes tantalum nitride (TaN), titanium nitride (TiN), tungsten nitride (WN), boron carbon doped tungsten (WBC), or some combination thereof. In an embodiment, the barrier layer 116 includes multiple layers, for example, a tantalum layer and a tantalum nitride layer. In a preferred embodiment, the barrier layer 116 includes a single layer of titanium nitride (TIN).

In an embodiment, the barrier layer 116 can be formed using a deposition technique including, for example, ALD, CVD, plasma enhanced chemical vapor deposition (PECVD), PVD, evaporation, spin-on coating, or sputtering.

In general, the barrier layer 116 may have a thickness sufficient to achieve desired barrier properties as is well known to persons having skill in the art. For example, the barrier layer 116 may have a typical thickness ranging from about 1 nm to about 4 nm, although thicknesses less than 1 nm or greater than 4 nm are explicitly contemplated.

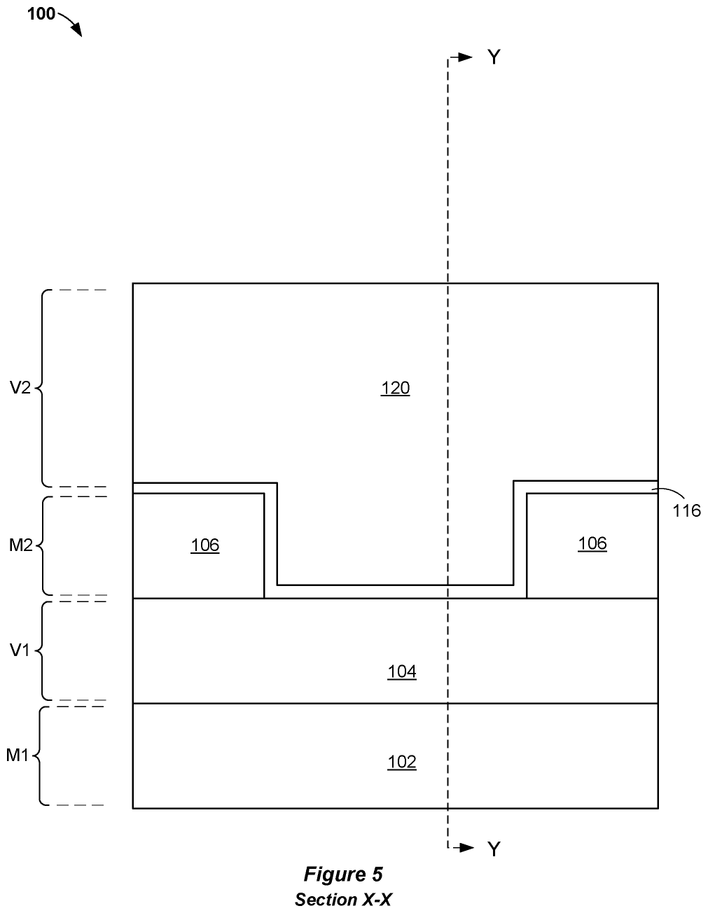

Referring now to FIG. 5, the structure 100 is shown according to an embodiment of the invention. FIG. 5 is a cross-sectional view of the structure 100 along section line X-X. A conductive material layer 120 may be formed.

The conductive material layer 120 is blanket deposited on top of the structure 100, and directly on a top surface of the barrier layer 116, filling the metal wire opening 112. The conductive material layer 120 may include materials such as, for example copper (Cu), ruthenium (Ru), cobalt (Co), tungsten (W). The conductive material layer 120 can be formed by for example, CVD, PVD, and ALD or a combination thereof. There may be any number of openings in the ILD 106, each filled with the barrier layer 116 and the conductive material layer 120, on the structure 100. The conductive material layer 120 is formed in both in the M2 metal line level and in the V2 via level above the M2 metal line level. The material of the conductive material layer 120 is used to form a metal line in the M2 metal line level and multiple vias in the V2 metal line level.

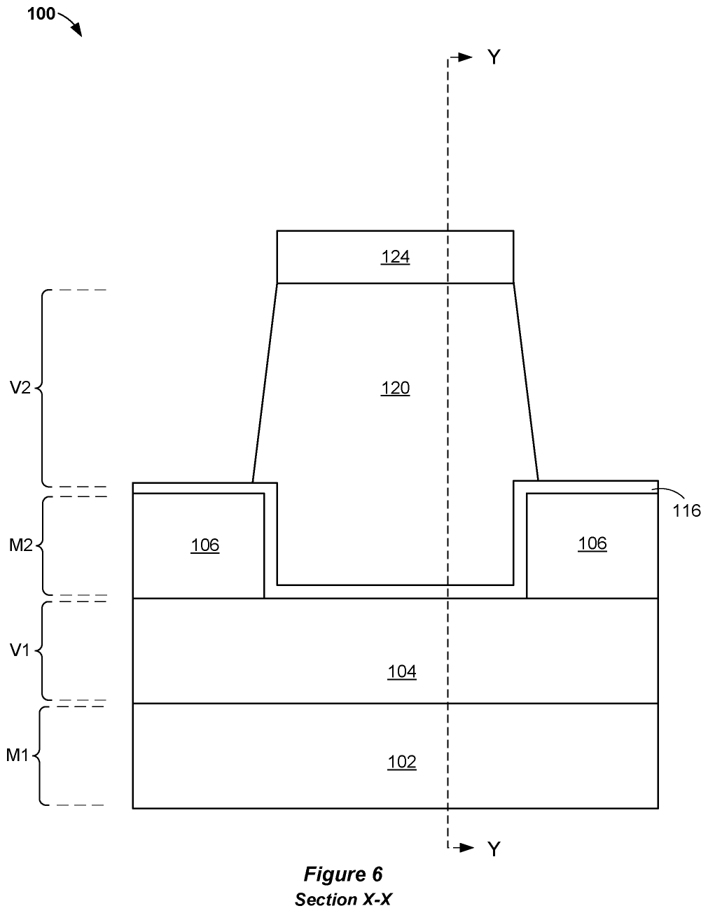

Referring now to FIG. 6, the structure 100 is shown according to an embodiment of the invention. FIG. 6 is a cross-sectional view of the structure 100 along section line X-X. A hard mask 124 may be formed and patterned. Portions of the conductive material layer 120 may be removed.

The hard mask 124 is formed according to embodiment of present invention. More particularly, the hard mask 124 may be formed to be vertically substantially aligned with the metal line opening 112 below, has a width that is equal to or larger than a width of the metal line opening 112, such that the subtractive etch process does not etch into the metal line opening 112. The hard mask 124 should have a shape of a via (in a top view such as a rectangular, square, or circle etc.) so that later a top portion of the conductive material layer 120 may be patterned into a via shape.

An etching technique is applied to remove portions of the conductive material layer 120, according to known techniques. Specifically, one or more dry etching techniques are used to remove portions of the conductive material layer 120, selective to the hard mask 124. Suitable dry etching techniques may include, but are not limited to: reactive ion etching (RIE), ion beam etching, plasma etching, or laser ablation. In all cases, the dry etching technique shall cause a lower portion of the conductive material layer 120 to remain in the metal wire opening 112 thereby forming a metal line. The remaining conductive material layer 120 overlaps a portion of an upper horizontal surface of the barrier layer 116 on the upper horizontal surface of the ILD 106. Remaining portions of the conductive material layer 120 extend above the metal line in the V2 via level and form one or more vias in the V2 via level. The conductive material layer 120 extends across both the M2 metal line level and the V2 via level and is formed within the same processes. The same process of forming the conductive material layer 120 forms both a metal line and a via.

The via of the V2 via level overlaps and extend wider than the metal line of the M2 metal line layer.

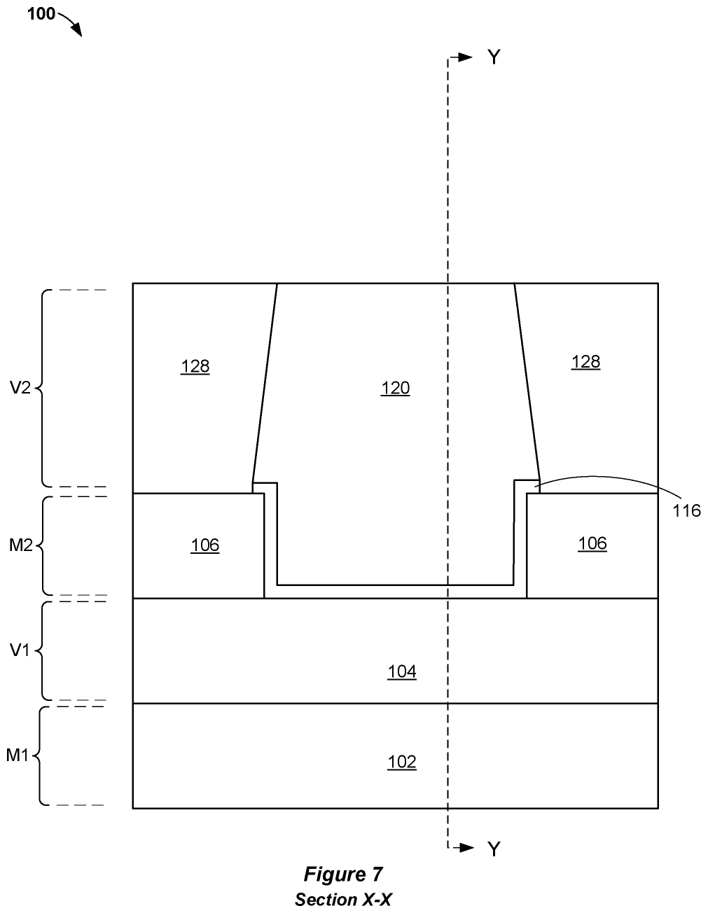

Referring now to FIG. 7, the structure 100 is shown according to an embodiment of the invention. FIG. 7 is a cross-sectional view of the structure 100 along section line X-X. Portions of the barrier layer 116 may be removed. The hard mask 124 may be removed. A dielectric cap 128 may be formed.

The portions of the barrier layer 116 which are not covered by the conductive material layer 120 are removed, exposing the upper horizontal surface of the ILD 106. An etching technique is applied to remove portions of the barrier layer 116.

The hard mask 124 is removed by methods known in the arts.

The dielectric cap 128 may be formed using a method as described forming the ILD 102. In an embodiment, the dielectric cap 128 may include any dielectric material such as silicon nitride (SiNx), silicon carbonitride (SiNC), a low-k dielectric material (with k<4.0), or any combination thereof or any other suitable dielectric material. The material of the dielectric cap 128 may be same or different from material of the ILD 106.

A planarization process such as, for example, a CMP process may be applied to remove excess material from a top surface of the structure 100 such that upper horizontal surfaces of the conductive material layer 120 and the dielectric cap 128 are coplanar.

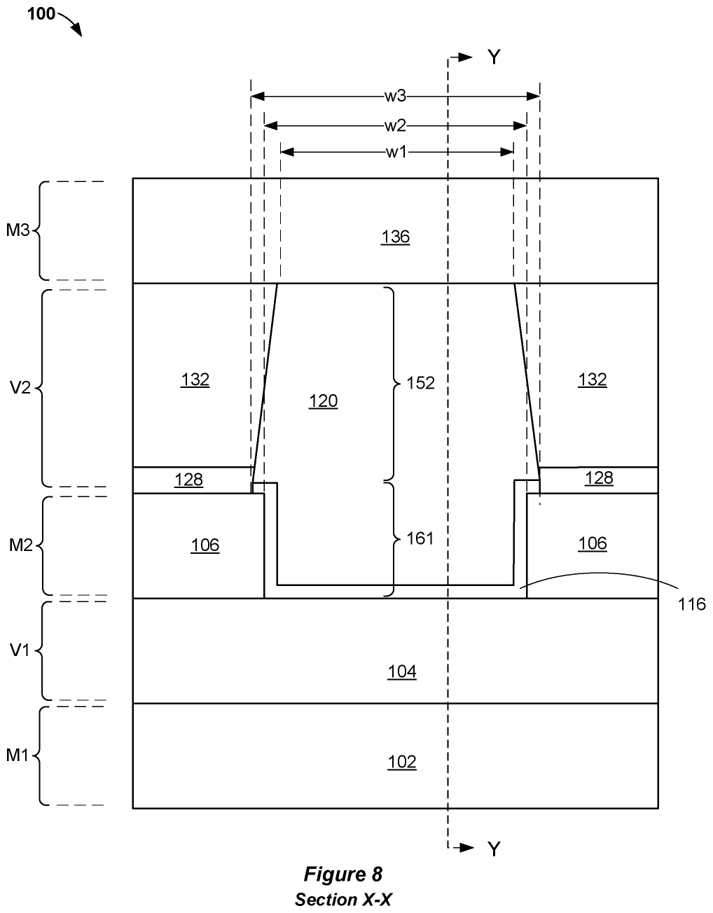

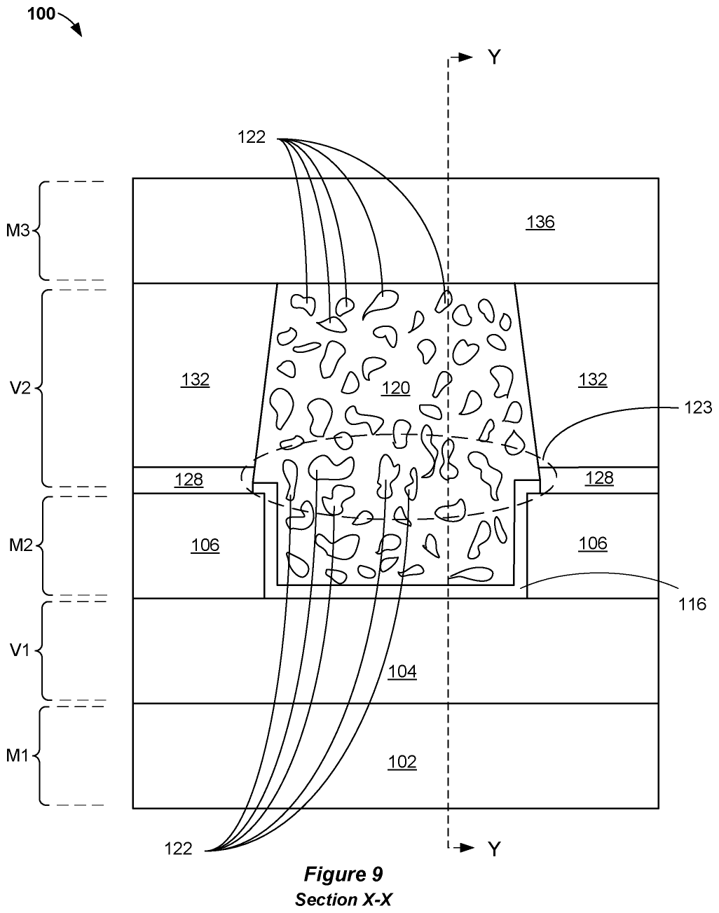

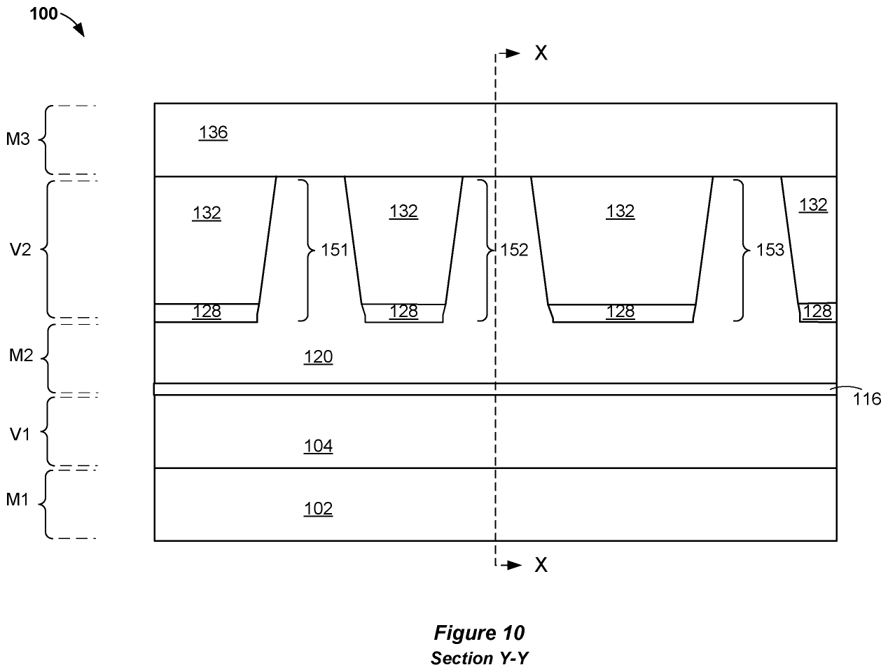

Referring now to FIGS. 8, 9 and 10, the structure 100 is shown according to an embodiment of the invention. FIGS. 8, 9 and 10 are each a cross-sectional view of the structure 100 along section lines X-X, X-X and Y-Y, respectively. FIGS. 8 and 9 are different illustrations of the same figure. The cross-section shown in FIGS. 8 and 9 are taken in a direction that is perpendicular to the direction taken for the cross-section of FIG. 10. Portions of the dielectric cap 128 may be removed. An inter-layer dielectric (hereinafter “ILD”) 132 may be formed. An inter-layer dielectric (hereinafter “ILD”) 136 may be formed.

An etching technique is applied to remove portions of the dielectric cap 128. Remaining portions of the dielectric cap 128 cover the horizontal surfaces of the ILD 106 and a portion of a vertical side surface of the conductive material layer 120. Remaining portions of the vertical side surface of the conductive material layer 120 are exposed by removal of the portions of the dielectric cap 128. The dielectric cap 128 may have a thickness ranging from about 10 nm to about 100 nm and ranges there between, although a thickness less than 10 nm or greater than 100 nm are explicitly contemplated.

The ILD 132 may be formed using a method as described forming the ILD 102. The ILD 132 may cover an upper horizontal surface of the dielectric cap 128 and previously exposed vertical side surfaces of the conductive material layer 120.

A planarization process, such as, for example, CMP, may be performed to remove excess material from a top surface of the structure 100 such that upper horizontal surfaces of the conductive material layer 120 and the ILD 132 are coplanar.

The ILD 136 may be formed on the structure 100, using a method as described forming the ILD 102. The ILD 136 may cover an upper horizontal surface of the dielectric cap 128 and vertical side surfaces of the conductive material layer 120. The ILD 136 forms the M3 metal line level above the V2 via level.

A planarization process, such as, for example, CMP, may be performed to remove excess material from a top surface of the structure 100 such that upper horizontal surfaces of the ILD 136 are coplanar.

The structure 100 includes the conductive material layer 120 which spans across the M2 metal line level and the V2 via level. The conductive material layer 120 in the M2 metal line level serves as a metal line and the conductive material layer 120 in the V2 via level serves as a via or vias. The conductive material layer 120 may form any number of metal lines, such as the metal line 161, in the M2 metal line level, and any number of vias in the V2 via level, such as vias 151, 152, and 153, as being demonstratively illustrated in FIG. 10. The metal lines, such as the metal line-161, in the M2 metal line level are formed by damascene and the vias, such the vias 151, 152, and 153, in the V2 via level are formed by subtractive etch patterning from the conductive material layer 120, using known patterning and etching techniques.

An upper metal wire (not shown) may be formed in the M3 metal line level. The upper metal wire may be formed by first patterning a trench (not shown) into the ILD 136, lining the trench with a liner (not shown), and filling the trench. A planarization process, such as, for example, CMP, may be done to remove excess material from a top surface of the structure 100 such that upper horizontal surfaces of the upper metal wire, the liner and the ILD 136 are coplanar. In an embodiment, the upper metal wire may have a thickness ranging from about 10 nm to about 100 nm, although a thickness less than 10 nm and greater than 100 nm may be acceptable.

The structure 100 has the conductive material layer 120 spanning the M2 metal line level and the V2 via level, and the conductive material layer 120 formed from one metallization process to form one or more metal lines and one or more vias. The resulting conductive material 120 structure includes a homogeneous material which has a reduced resistance between the metal line and the via. This is achieved as the continuous formation of the conductive material layer forms both the metal line and the via without creating liner or barrier between the metal line and the via. This has a lower resistance than a structure with separately formed metal line and via which usually includes liners between the metal line and via thereby resulting in higher resistance. The homogeneous conductive metal structure includes both a metal line in the M2 metal line level and a via in the V2 via level.

The via, in bracketed area 152, has a width, w1, at an upper horizontal which is less than a width of the via, in the bracketed area 152, at a lower horizontal surface, w2. The metal line, in the bracketed area 161, has a width, w3, which is less the width w2. The metal line, in the bracketed area 161, and the barrier layer 116 has a combined width which is less the width w2. The via, in the bracketed area 152, flares out and overlaps an upper horizontal portion of the ILD 106 surrounding the metal line, in the bracketed area 161. A portion of the barrier layer 116 overlaps the upper horizontal portion of the ILD 106. The barrier layer 116 has a first lower horizontal surface directly adjacent to an upper horizontal surface of the ILD 104 and horizontally aligned with a lower horizontal surface of the ILD 106. The barrier layer has a second lower horizontal surface directly adjacent to an upper horizontal surface of the ILD 106.

FIG. 9 illustrates metal grains within the conductive material layer 120. When the conductive material layer 120 is formed, individual crystalline areas are formed within the conductive material layer 120 and may be referred to as grains. Individual grains 122 are illustrated within the conductive material layer 120. A size, orientation and structure of the grains 122 are dependent upon a material used and a temperature and conditions of forming the conductive material layer 120. As illustrated in circled area 123, there are several individual grains 122 which span across both the via portion of the conductive material layer 120 in the V2 level and the metal line portion of the conductive material layer 120 in the M2 level. The individual grains 122 span both the via and the metal line due to the via and the metal line being formed during the same process of forming the conductive material layer 120.

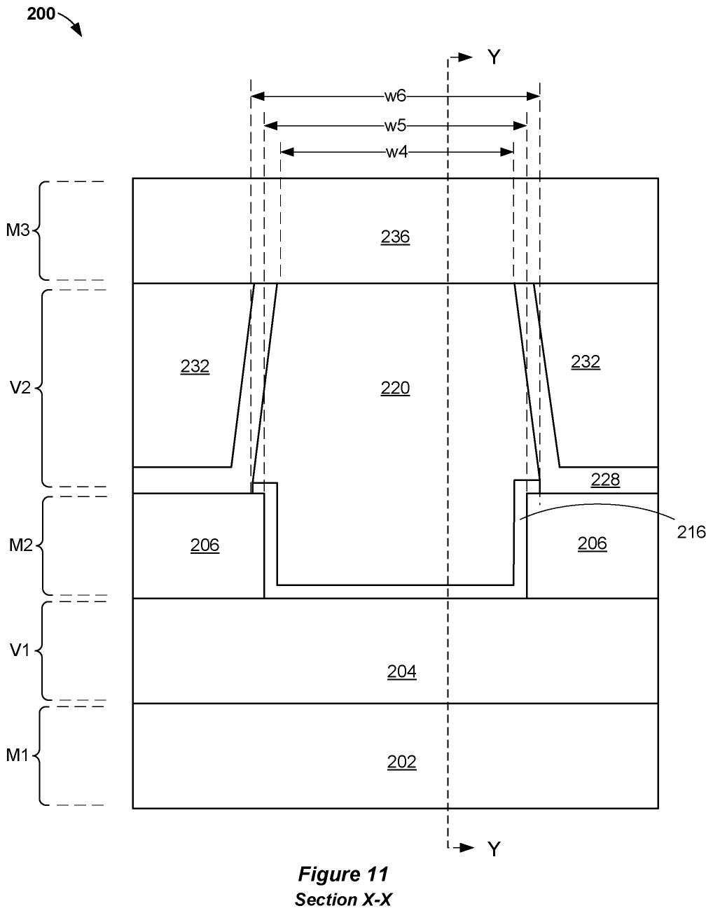

Referring now to FIG. 11, a semiconductor structure 200 (hereinafter “structure”) is shown during an intermediate step of a method of fabricating a low resistance via, according to an embodiment of the invention. FIG. 11 is a cross-sectional view of the structure 200 along section line X-X. The structure 200 may be formed or provided. The structure 200 may include an ILD 202, a liner 204, a lower metal wire 206, a dielectric cap 208, an ILD 210 and a via opening 212.

The structure 200 includes an M1 metal line level, a V1 via level, an M2 metal line level, a V2 via level and a M3 metal line level. The structure 200 may include an ILD 202 in the M1 metal line level, an ILD 204 in the V1 via level above the M1 metal line level, an ILD 206 in the M2 metal line level above the V1 via level, an ILD 232 in the V2 via level above the M2 metal line level, and an ILD 236 in the M3 metal line level above the V2 via level D. The structure 200 includes a barrier layer 216, a conductive material layer 220 and a dielectric cap 228.

The structure 200 is an alternate embodiment of the invention. Structures with similar names in the FIG. 200 may be formed as described for the structure 100. The difference between the structure 100 and the structure 200 is that the dielectric cap 228 remains on vertical side surfaces of the conductive material layer 220 in the V2 via level in the structure 200. In the structure 100, the conductive material layer 120 is removed from vertical side surfaces of the conductive material layer 120 in the V2 via level.

The structure 200 has the conductive material layer 220 spanning the M2 metal line level and the V2 via level, and the conductive material layer 220 simultaneously forms one or more metal lines and one or more vias. The resulting structure has a reduced via resistance between the metal line and the via, as the continuous formation of the conductive material layer forms both the metal line and the via and thus there is no liner nor barriers between the metal line and the via.

According to an embodiment of the present invention, a semiconductor structure is provided. The semiconductor structure includes metal structure which spans vertically across a M1 metal line level and a via in a V1 via level above the M1 metal line level, where an individual metal grain of the metal structure spans from the metal line in the M1 metal line level and the via in the V1 via level.

An embodiment further includes an inter-level dielectric surrounding the metal line and a barrier layer separating a lower horizontal surface and vertical side surfaces of the metal line of the metal structure from the inter-layer dielectric. An embodiment further includes a dielectric cap on an upper horizontal surface of the inter-layer dielectric. An embodiment where a lower horizontal surface of the via covers a portion of an upper horizontal surface of the inter-level dielectric surrounding the metal line. An embodiment where a first lower horizontal surface of the barrier layer covers a portion of an upper horizontal surface of the inter-level dielectric surrounding the metal line. An embodiment where the metal structure includes a second via in the V1 via level. An embodiment where a width of a lower horizontal surface of the via portion of the metal structure is greater than a width of the metal line portion of the metal structure. An embodiment further includes a second metal line in a M2 metal line layer above the V1 via level, connected to the via.

According to an embodiment of the present invention, a semiconductor structure is provided. The semiconductor structure including a metal line in a M1 metal line level and a via in a V1 via level above the M1 metal line level, where the metal line and the via form one continuous metal structure.

An embodiment further includes a second metal line in a M2 metal line layer above the V1 via level, connected to the via. An embodiment further includes an inter-level dielectric surrounding the metal line and a barrier layer separating a lower horizontal surface and vertical side surfaces of the metal line from the inter-layer dielectric. An embodiment further includes a dielectric cap on an upper horizontal surface of the inter-layer dielectric. An embodiment where a lower horizontal surface of the via covers a portion of an upper horizontal surface of the inter-level dielectric. An embodiment where a first lower horizontal surface of the barrier layer covers a portion of an upper horizontal surface of the inter-level dielectric. An embodiment further includes including a second via in the V1 via level. An embodiment where a width of a lower horizontal surface of the via portion of the metal structure is greater than a width of the metal line portion of the metal structure.

According to an embodiment of the present invention, a semiconductor structure is provided. The semiconductor structure including a metal line in a M1 metal line level and a set of vias in a V1 via level above the M1 metal line level, where the metal line and the set of vias are one continuous metal structure.

An embodiment further includes an inter-level dielectric surrounding the metal line and a barrier layer separating a lower horizontal surface and vertical side surfaces of the metal line from the inter-layer dielectric. An embodiment where a lower horizontal surface of each of the vias of the set of vias covers a portion of an upper horizontal surface of the inter-level dielectric. An embodiment where a width of a lower horizontal surface of each of the vias in the via portion of the metal structure is greater than a width of the metal line portion of the metal structure.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a metal structure which spans vertically across a M1 metal line level and a V1 via level above the M1 metal line level, wherein the metal structure comprises both a metal line in the M1 metal line level and a via in the V1 via level, wherein an individual metal grain of the metal structure spans from the metal line in the M1 metal line level to the via in the V1 via level.

2. The semiconductor structure according to claim 1, further comprising:
an inter-level dielectric surrounding the metal line; and
a barrier layer separating a lower horizontal surface and vertical side surfaces of the metal line of the metal structure from the inter-layer dielectric.

3. The semiconductor structure according to claim 2, further comprising:
a dielectric cap on an upper horizontal surface of the inter-layer dielectric.

4. The semiconductor structure according to claim 2, wherein a lower horizontal surface of the via covers a portion of an upper horizontal surface of the inter-level dielectric surrounding the metal line.

5. The semiconductor structure according to claim 2, wherein a first lower horizontal surface of the barrier layer covers a portion of an upper horizontal surface of the inter-level dielectric surrounding the metal line.

6. The semiconductor structure according to claim 1, wherein the metal structure comprises a second via in the V2 via level.

7. The semiconductor structure according to claim 1, wherein a width of a lower horizontal surface of the via portion of the metal structure is greater than a width of the metal line portion of the metal structure.

8. The semiconductor structure according to claim 1, further comprising:
a second metal line in a M3 metal line layer above the V2 via level, connected to the via.

9. A semiconductor structure comprising:
a metal line in a M1 metal line level; and
a via in a V1 via level above the M1 metal line level,
wherein the metal line and the via form one continuous metal structure.

10. The semiconductor structure according to claim 9, further comprising:
a second metal line in a M2 metal line layer above the V1 via level, connected to the via.

11. The semiconductor structure according to claim 9, further comprising:
an inter-level dielectric surrounding the metal line; and
a barrier layer separating a lower horizontal surface and vertical side surfaces of the metal line from the inter-layer dielectric.

12. The semiconductor structure according to claim 11, further comprising:
a dielectric cap on an upper horizontal surface of the inter-layer dielectric.

13. The semiconductor structure according to claim 11, wherein a lower horizontal surface of the via covers a portion of an upper horizontal surface of the inter-level dielectric.

14. The semiconductor structure according to claim 11, wherein a first lower horizontal surface of the barrier layer covers a portion of an upper horizontal surface of the inter-level dielectric.

15. The semiconductor structure according to claim 9, further comprising a second via in the V1 via level.

16. The semiconductor structure according to claim 9, wherein a width of a lower horizontal surface of the via of the one continuous metal structure is greater than a width of the metal line of the one continuous metal structure.

17. A semiconductor structure comprising:
a metal line in a M1 metal line level; and
a set of vias in a V1 via level above the M1 metal line level,
wherein the metal line and the set of vias are one continuous metal structure.

18. The semiconductor structure according to claim 17, further comprising:
an inter-level dielectric surrounding the metal line; and
a barrier layer separating a lower horizontal surface and vertical side surfaces of the metal line from the inter-layer dielectric.

19. The semiconductor structure according to claim 17, wherein a lower horizontal surface of each of the vias of the set of vias covers a portion of an upper horizontal surface of the inter-level dielectric.

20. The semiconductor structure according to claim 17, wherein a width of a lower horizontal surface of each of the vias in the set of vias of the one continuous metal structure is greater than a width of the metal line portion of the one continuous metal structure
